(19) United States
(12) Patent Application Publication
(10) Pub. No.: US 2016/0160331 A1
(43) Pub. Date: Jun. 9, 2016

(54) AMORPHOUS THIN METAL FILM

(71) Applicant: HEWLETT-PACKARD DEVELOPMENT COMPANY, L.P., Houston, TX (US)

(72) Inventors: James Elmer ABBOTT, JR., Corvallis, OR (US); Arun K. AGARWAL, Corvallis, OR (US); Roberto A. PUGLIESE, Corvallis, OR (US); Greg Scott LONG, Corvallis, OR (US); Stephen HORVATH, San Diego, CA (US); John WAGER, Corvallis, OR (US); Douglas A. KESZLER, Corvallis, OR (US); Kristopher OLSEN, Corvallis, OR (US); John MCGLONE, Corvallis, OR (US)

(73) Assignees: Hewlett-Packard Development Company, L.P., Houston, TX (US); Oregon State University, Corvallis, OR (US)

(21) Appl. No.: 14/787,638

(22) PCT Filed: Jul. 12, 2013
(86) PCT No.: PCT/US2013/050192

§ 371 Date: Oct. 28, 2015

(51) Int. Cl. C22C 45/10; C23C 14/34; C23C 14/14

(52) U.S. Cl. CPC C22C 45/10; C23C 14/14; C23C 14/34

(57) ABSTRACT

The present disclosure is drawn to amorphous thin metal films and associated methods. Generally, an amorphous thin metal film can comprise a combination of three metals or metalloids including: 5 at % to 90 at % of a metalloid selected from the group of carbon, silicon, and boron; 5 at % to 90 at % of a first metal selected from the group of titanium, vanadium, chromium, cobalt, nickel, zirconium, niobium, molybdenum, rhodium, palladium, hafnium, tantalum, tungsten, iridium, and platinum; and 5 at % to 90 at % of a second metal selected from the group of titanium, vanadium, chromium, cobalt, nickel, zirconium, niobium, molybdenum, rhodium, palladium, hafnium, tantalum, tungsten, iridium, and platinum, wherein the second metal is different than the first metal. Typically, the three elements account for at least 70 at % of the amorphous thin metal film.

### BACKGROUND

Thin metal films can be used in various applications such as electronic semiconductor devices, optical coatings, and printing technologies. As such, once deposited, thin metal films can be subjected to harsh environments. Such thin films may be subjected to high heat, corrosive chemicals, etc.

For example, in a typical inkjet printing system, an inkjet printhead ejects fluid (e.g., ink) droplets through a plurality of nozzles toward a print medium, such as a sheet of paper, to print an image onto the print medium. The nozzles are generally arranged in one or more arrays, such that properly sequenced ejection of ink from the nozzles causes characters or other images to be printed on the print medium as the printhead and the print medium are moved relative to each other.

Unfortunately, because the ejection process is repeated thousands of times per second during printing, collapsing vapor bubbles also have the adverse effect of damaging the heating element. The repeated collapsing of the vapor bubbles leads to cavitation damage to the surface material that coats the heating element. Each of the millions of collapse events ablates the coating material. Once ink penetrates the surface material coating the heating element and contacts the hot, high voltage resistor surface, rapid corrosion and physical destruction of the resistor soon follows, rendering the heating element ineffective. There are also other examples of systems, outside of the inkjet arts, where structures may undergo contact with harsh environments. As such, research and development continues in the area of thin metal films used in various applications that can provide improved performance.

### BRIEF DESCRIPTION OF THE DRAWINGS

Additional features and advantages of the invention will be apparent from the detailed description which follows, taken in conjunction with the accompanying drawings, which together illustrate, by way of example, features of the invention.

FIG. 1 is a figure of a schematic cross-sectional view of a distribution of elements of an amorphous thin metal film in accordance with one example of the present disclosure; and

FIG. 2 is a figure of a lattice structure of an amorphous thin metal film in accordance with one example of the present disclosure.

Reference will now be made to the exemplary embodiments illustrated, and specific language will be used herein to describe the same. It will nevertheless be understood that no limitation of the scope of the invention is thereby intended.

### DETAILED DESCRIPTION

Before the present invention is disclosed and described, it is to be understood that this disclosure is not limited to the particular process steps and materials disclosed herein because such process steps and materials may vary somewhat. It is also to be understood that the terminology used herein is used for the purpose of describing particular embodiments only. The terms are not intended to be limiting because the scope of the present invention is intended to be limited only by the appended claims and equivalents thereof.

It has been recognized that it would be advantageous to develop amorphous thin metal films that are stable having robust chemical, thermal, and mechanical properties. Specifically, it has been recognized that many thin metal films generally have a crystalline structure that possess grain boundaries and a rough surface. Notably, such characteristics hamper the thin metal film's chemical, thermal, and mechanical properties. However, it has been discovered that thin metal films can be made from a three component system providing a stable and amorphous structure having superior chemical, thermal, and mechanical properties.

In accordance with this, the present disclosure is drawn to an amorphous thin metal film comprising a combination of three elements. It is noted that when discussing an amorphous thin metal film or a method of manufacturing an amorphous thin metal film, each of these discussions can be considered applicable to each of these embodiments, whether or not they are explicitly discussed in the context of that embodiment. Thus, for example, in discussing a metalloid for an amorphous thin metal film, such a metalloid can also be used in a method of manufacturing an amorphous thin metal film, and vice versa.

As such, with the present discussion in mind, an amorphous thin metal film can comprise a combination of three elements including: 5 atomic % (at %) to 90 at % of a metalloid that can be carbon, silicon, or boron; 5 at % to 90 at % of a first metal that can be titanium, vanadium, chromium, cobalt, nickel, zirconium, niobium, molybdenum, rhodium, palladium, hafnium, tantalum, tungsten, iridium, or platinum; and 5 at % to 90 at % of a second metal that can be titanium, vanadium, chromium, cobalt, nickel, zirconium, niobium, molybdenum, rhodium, palladium, hafnium, tantalum, tungsten, iridium, or platinum. In this example, the second metal is different than the first metal. Generally, the three elements account for at least 70 at % of the amorphous thin metal film, or alternatively, two elements can account for at least 70 at % of the amorphous thin metal film. This range of metalloid, first metal, and second metal, can likewise be independently modified at the lower end to 10 atomic %, or 20 atomic %, and/or at the upper end to 40 atomic %, 50 atomic %, 70 atomic %, or 80 atomic %. Furthermore, in one example, the metalloid, the first metal, and the second metal can account for at least 80 atomic %, at least 90 atomic %, or even 100 atomic % of the amorphous thin metal film.

The present three component mixture of elements can be mixed in a manner and in quantities that the mixture is homogenous. Additionally, the mixture can be sintered and further applied to a suitable substrate using deposition techniques. Generally, the resulting thin metal film is amorphous. By using three components in high enough concentrations, a “confusion” of sizes and properties disfavors the formation of lattice structures that are more typical in single component or even two component systems. Selecting components with suitable size differentials can contribute to minimizing crystallization of the structure. For example, the amorphous thin metal film may have an atomic dispersity of at least 12% between two of the three elements. In another aspect, the amorphous thin metal film may an atomic dispersity of at least 12% between all three of elements, e.g., metalloid, first metal, and second metal. As used herein, “atomic dispersity” refers to the difference in size between the radii of two atoms. In one example, the atomic dispersity can be at least 15%, and in one aspect, can be at least 20%. The atomic dispersity between components can contribute to the exceptional properties of the present films, including thermal stability, oxidative stability, chemical stability, and surface roughness, which are not achieved by typical thin metal films. Oxidative stability can be measured by the amorphous thin metal film's oxidation temperature and/or oxide growth rate as discussed herein.

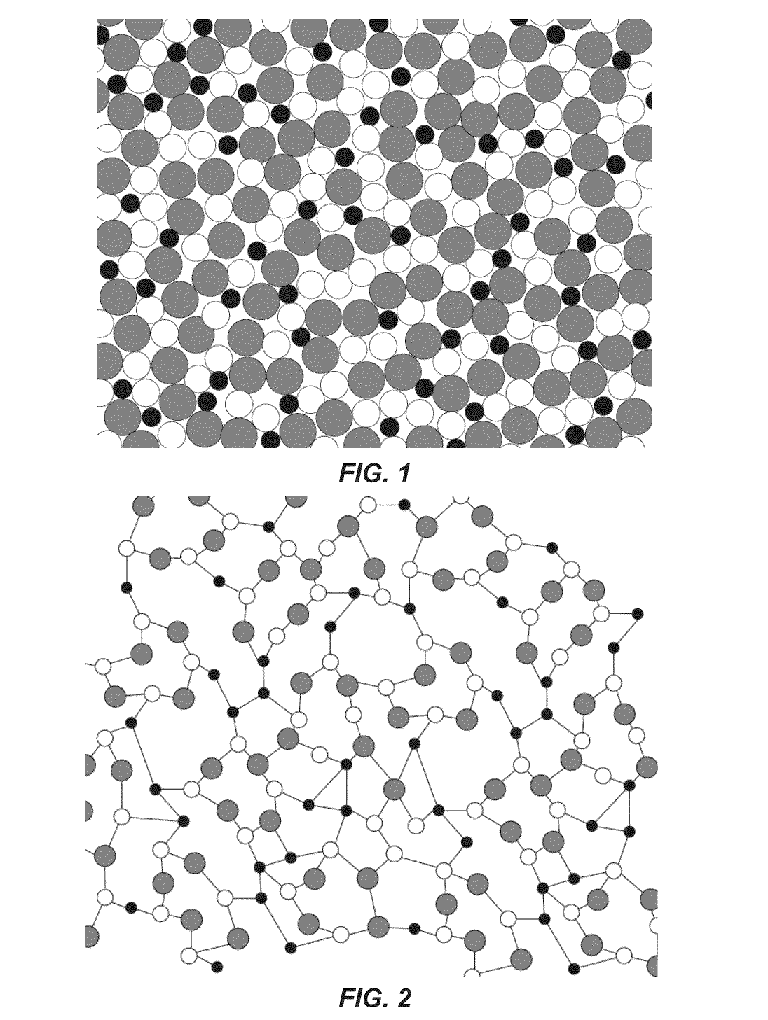

Turning now to FIG. 1, the present thin metal films can have a distribution of components with an atomic dispersity as represented in FIG. 1. Notably, the present thin metal films can be generally amorphous with a smooth, grain-free structure. Turning now to FIG. 2, the lattice structure of the present amorphous thin metal films can be represented by FIG. 2 as compared to typical films with a more crystalline lattice structure having grain boundaries.

As discussed herein, the present amorphous thin metal films can have exceptional properties including thermal stability, oxidative stability, and surface roughness. In one example, the present thin metal films can have a root mean square (RMS) roughness of less than 1 nm. In one aspect, the RMS roughness can be less than 0.5 nm. In another aspect, the RMS roughness can be less than 0.1 nm. One method to measure the RMS roughness includes measuring atomic force microscopy (AFM) over a 100 nm by 100 nm area. In other aspects, the AFM can be measured over a 10 nm by 10 nm area, a 50 nm by 50 nm area, or a 1 micron by 1 micron area. Other light scattering techniques can also be used such as x-ray reflectivity or spectroscopic ellipsometry.

In another example, the amorphous thin metal film can have a thermal stability of at least 400° C. In one aspect, the thermal stability can be at least 800° C. In another aspect, the thermal stability can be at least 900° C. As used herein, “thermal stability” refers to the maximum temperature that the amorphous thin metal film can be heated while maintaining an amorphous structure. One method to measure the thermal stability includes sealing the amorphous thin metal film in a quartz tube, heating the tube to a temperature, and using x-ray diffraction to evaluate the atomic structure and degree of atomic ordering.

In still another example, the amorphous thin metal film can have an oxidation temperature of at least 700° C. In one aspect, the oxidation temperature can be at least 800° C., and in another aspect, at least 1000° C. As used herein, the oxidation temperature is the maximum temperature that the amorphous thin metal film can be exposed before failure of the thin film due to stress creation and embrittlement of the partially or completely oxidized thin film. One method to measure the oxidation temperature is to heat the amorphous thin metal film at progressively increasing temperatures in air until the thin film cracks and flaks off the substrate.

In another example, the amorphous thin metal film can have an oxide growth rate of less than 0.05 mm/min. In one aspect, the oxide growth rate can be less than 0.04 mm/min, or in another aspect, less than 0.03 mm/min. One method to measure the oxide growth rate is to heat the amorphous thin metal film under air (20% oxygen) at a temperature of 300° C., measure the amount of oxidation on the amorphous thin metal film using spectroscopic ellipsometry periodically, and average the data to provide a nm/min rate. Depending on the components and the method of manufacture, the amorphous thin metal film can have a wide range of electric resistivity, including ranging from 100 μΩ·cm to 2000 μΩ·cm.

Generally, the amorphous thin metal film can have a positive heat of mixing. As discussed herein, the present thin metal films generally include a metalloid, a first metal, and a second metal, where the first and second metal can include elements selected from Periodic Table Groups IV, V, VI, IX, and X (4, 5, 6, 9, and 10). In one example, the amorphous thin metal films can include a refractory metal selected from the group of titanium, vanadium, chromium, zirconium, niobium, molybdenum, rhodium, hafnium, tantalum, tungsten, and iridium. In one aspect, the first and/or second metal can be present in the thin film in an amount ranging from 20 at % to 90 at %. In another aspect, the first and/or second metal can be present in the thin film in an amount ranging from 20 at % to 40 at %.

Additionally, the amorphous thin metal films can further include a dopant. In one example, the dopant can include nitrogen, oxygen, and mixtures thereof. The dopant can generally be present in the amorphous thin metal film in an amount ranging from 0.1 at % to 15 at %. In one example, the dopant can be present in an amount ranging from 0.1 at % to 5 at %. Smaller amounts of dopants can also be present, but at such low concentrations, they would typically be considered impurities. Additionally, in one aspect, the amorphous thin metal film can be devoid of aluminum, silver, and gold.

Generally, the amorphous thin metal film can have a thickness ranging from 10 angstroms to 100 microns. In one example, the thickness can be from 10 angstroms to 2 microns. In one aspect, the thickness can be from 0.05 microns to 0.5 microns.

Turning now to a method of manufacturing an amorphous thin metal film, the method can comprise depositing a metalloid and a first and second metal to a substrate to form the amorphous thin metal film. The thin metal film can comprise 5 at % to 90 at % of the metalloid selected from the group of carbon, silicon, and boron; 5 at % to 90 at % of the first metal selected from the group of titanium, vanadium, chromium, cobalt, nickel, zirconium, niobium, molybdenum, rhodium, palladium, hafnium, tantalum, tungsten, iridium, and platinum; and 5 at % to 90 at % of the second metal selected from the group of titanium, vanadium, chromium, cobalt, nickel, zirconium, niobium, molybdenum, rhodium, palladium, hafnium, tantalum, tungsten, iridium, and platinum, wherein the second metal different than the first metal. In another example, prior to depositing, the metalloid, the first metal, and the second metal can be mixed to form a blend that can be subsequently deposited.

Generally, the step of depositing can include sputtering, atomic layer deposition, chemical vapor deposition, electron beam deposition, or thermal evaporation. In one example, the depositing can be sputtering. The sputtering can generally be performed at 5 to 15 mTorr at a deposition rate of 5 to 10 nm/min with the target approximately 4 inches from a stationary substrate. Other deposition conditions may be used and other deposition rates can be achieved depending on variables such as target size, electrical power used, pressure, sputter gas, target to substrate spacing and a variety of other deposition system dependent variables. In another aspect, depositing can be performed in the presence of a dopant that is incorporated into the thin film. In another specific aspect, the dopant can be oxygen and/or nitrogen.

Notably, it has been recognized that amorphous thin metal films as discussed herein can have exceptional properties including thermal stability, oxidative stability, chemical stability, and surface roughness. As such, the present thin metal films can be used in a number of applications including electronic semiconductor devices, optical coatings, and printing technologies, for example.

It is noted that, as used in this specification and the appended claims, the singular forms “a,” “an,” and “the” include plural referents unless the context clearly dictates otherwise.

As used herein, “devoid of” refers to the absence of materials in quantities other than trace amounts, such as impurities.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 at % to about 5 at %” should be interpreted to include not only the explicitly recited values of about 1 at % to about 5 at %, but also include individual values and sub-ranges within the indicated range. Thus, included in this numerical range are individual values such as 2, 3.5, and 4 and sub-ranges such as from 1-3, from 2-4, and from 3-5, etc. This same principle applies to ranges reciting only one numerical value. Furthermore, such an interpretation should apply regardless of the breadth of the range or the characteristics being described.

### EXAMPLES

The following examples illustrate embodiments of the disclosure that are presently known. Thus, these examples should not be considered as limitations of the invention, but are merely in place to teach how to make compositions of the present disclosure. As such, a representative number of compositions and their method of manufacture are disclosed herein.

### Example 1

### Thin Metal Films

Various thin metal films were prepared by DC and RF sputtering at 5 mTorr to 15 mTorr under argon, RF at 50 W to 100 W, and DC at 35 W to 55 W on to a silicon wafer. The resulting film thickness was in the range of 100 nm to 500 nm. The specific components and amounts are listed in Table 1.

TABLE 1

| | Ratio | Ratio* |
|---|---|---|
| Thin Film Composition | (atomic %) | (weight %) |
| TaNiSi | 40:40:20 | 71:23:6 |
| TaWSi | 40:40:20 | 48:49:4 |
| TaWSi | 30:50:20 | 36:61:4 |
| TaMoSi | 40:40:20 | 62:33:5 |
| TaPtSi | 40:40:20 | 46:50:4 |

*Weight ratio calculated from atomic % and rounded to the nearest integer

### Example 2

### Thin Metal Films

MN Various thin metal films are prepared by DC and RF sputtering at 5 mTorr to 15 mTorr under argon, RF at 50 W to 100 W, and DC at 35 W to 55 W on to a silicon wafer. The resulting film thickness is in the range of 100 nm to 500 nm. The specific components and amounts are listed in Table 2.

TABLE 2

| | Ratio | Ratio* |
|---|---|---|
| Thin Film Composition | (atomic %) | (weight %) |
| TaCoB | 60:30:10 | 85:14:1 |
| NbWB | 50:40:10 | 38:61:1 |
| MoPtC | 40:50:10 | 28:71:1 |
| WTiC | 30:40:30 | 71:25:5 |
| MoNiSi | 45:40:5 | 63:35:2 |

*Weight ratio calculated from atomic % and rounded to the nearest integer

### Example 3

### Thin Metal Film Properties

The amorphous thin metal films of Example 1 were tested for electrical resistivity, thermal stability, chemical stability, oxidation temperature, and oxide growth rate. The results are listed in Table 3. All of the films had a surface RMS roughness of less than 1 nm.

Surface RMS roughness was measured by atomic force microscopy (AFM). Electrical resistivity was measured by collinear four point probe for different deposition conditions providing the range listed in Table 3. Thermal Stability was measured by sealing the amorphous thin metal film in a quartz tube at approximately 50 mTorr and annealing up to the temperature reported with x-ray confirmation of the amorphous state, where the x-ray diffraction patterns showed evidence of Bragg reflections. Chemical stability was measured by immersing the amorphous thin metal film in Hewlett Packard commercial inks CH602SERIES, HP Bonding Agent for Web Press; CH585SERIES, HP Bonding Agent for Web Press; and CH598SERIES, HP Black Pigment Ink for Web Press; at 55° C. and checked at 2 and 4 weeks. Adequate chemical stability was present with the thin film showed no visual physical change or delamination, indicated by a “Yes” in Table 3. Oxidation temperature was measured as the maximum temperature that the amorphous thin metal film can be exposed before failure of the thin film due to stress creation and embrittlement of the partially or completely oxidized thin film. Oxide growth rate was measured by heating the amorphous thin metal film under air (20% oxygen) at a temperature of 300° C., measuring the amount of oxidation on the amorphous thin metal film using spectroscopic ellipsometry periodically over a periods of 15, 30, 45, 60, 90, and 120 minutes, and then at 12 hours, and averaging the data to provide a nm/min rate.

TABLE 3

| | | | | | | Oxide |
|---|---|---|---|---|---|---|
| Thin | | Electric | Thermal | | Oxidation | Growth |
| Film | Ratio | Resistivity | Stability | Chemical | Temperature | Rate |
| Composition | (at. %) | (μΩ · cm) | (° C.) | Stability | (° C.) | (nm/min) |
| TaNiSi | 40:40:20 | 230-440 | 500 | Yes | 700 | 0.035 |
| TaWSi | 40:40:20 | 210-255 | 900 | Yes | 1000 | 0.027* |
| TaWSi | 30:50:20 | 210-1500 | 900 | Yes | Not tested | 0.049* |
| TaMoSi | 40:40:20 | 165-1000 | 900 | Yes | Not tested | 0.132* |
| TaPtSi | 40:40:20 | 300 | 400 | Yes | Not tested | 0 |

* Showed evidence of passivation (decreased growth rate) after appox. 60 minutes

While the invention has been described with reference to certain preferred embodiments, those skilled in the art will appreciate that various modifications, changes, omissions, and substitutions can be made without departing from the spirit of the invention. It is intended, therefore, that the invention be limited only by the scope of the following claims.

What is claimed is:

1. An amorphous thin metal film, comprising:
5 atomic % to 90 atomic % of a metalloid, wherein the metalloid is carbon, silicon, or boron;
5 atomic % to 90 atomic % of a first metal, wherein the first metal is titanium, vanadium, chromium, cobalt, nickel, zirconium, niobium, molybdenum, rhodium, palladium, hafnium, tantalum, tungsten, iridium, or platinum; and
5 atomic % to 90 atomic % of a second metal, wherein the second metal is titanium, vanadium, chromium, cobalt, nickel, zirconium, niobium, molybdenum, rhodium, palladium, hafnium, tantalum, tungsten, iridium, or platinum, wherein the second metal is different than the first metal,
wherein the metalloid, the first metal, and the second metal account for at least 70 atomic % of the amorphous thin metal film.

2. The amorphous thin metal film of claim 1, wherein the amorphous thin metal film has a thickness ranging from 10 angstroms to 100 microns.

3. The amorphous thin metal film of claim 1, wherein the amorphous thin metal film is devoid of aluminum, silver, and gold.

4. The amorphous thin metal film of claim 1, further comprising 0.1 atomic % to 15 atomic % of a dopant, the dopant being nitrogen, oxygen, or mixtures thereof.

5. The amorphous thin metal film of claim 1, wherein the amorphous thin metal film includes a refractory metal, the refractory metal being titanium, vanadium, chromium, zirconium, niobium, molybdenum, rhodium, hafnium, tantalum, tungsten, or iridium.

6. The amorphous thin metal film of claim 1, wherein the amorphous thin metal film has a surface RMS roughness of less than 1 nm.

7. The amorphous thin metal film of claim 1, wherein the amorphous thin metal film has a thermal stability of at least 400° C. and has an oxidation temperature of at least 700° C.

8. The amorphous thin metal film of claim 1, wherein the amorphous thin metal film has a thermal stability of at least 800° C. and has an oxidation temperature of at least 800° C.

9. The amorphous thin metal film of claim 1, wherein the amorphous thin metal film has an oxide growth rate of less than 0.05 nm/min.

10. The amorphous thin metal film of claim 1, wherein the amorphous thin metal film has a positive heat of mixing.

11. The amorphous thin metal film of claim 1, wherein the amorphous thin metal film has an atomic dispersity of at least 12% between at least two of the metalloid, the first metal, and the second metal relative to one another.

12. The amorphous thin metal film of claim 1, wherein the amorphous thin metal film has an atomic dispersity of at least 12% between each of the metalloid, the first metal, and the second metal relative to one another.

13. A method of manufacturing an amorphous thin metal film, comprising depositing:
i) 5 atomic % to 90 atomic % of a metalloid, wherein the metalloid is carbon, silicon, or boron;
ii) 5 atomic % to 90 atomic % of a first metal, wherein the first metal is titanium, vanadium, chromium, cobalt, nickel, zirconium, niobium, molybdenum, rhodium, palladium, hafnium, tantalum, tungsten, iridium, or platinum; and
iii) 5 atomic % to 90 atomic % of a second metal, wherein the second metal is titanium, vanadium, chromium, cobalt, nickel, zirconium, niobium, molybdenum, rhodium, palladium, hafnium, tantalum, tungsten, iridium, or platinum, and wherein the second metal is different than the first metal, to a substrate to form the amorphous thin metal film.

14. The method of claim 13, wherein the depositing includes sputtering.

15. The method of claim 13, wherein prior to depositing, the metalloid, the first metal, and the second metal are mixed to form a blend.
